(19) United States
(12) Patent Application Publication
(10) Pub. No.: US 2012/0280944 A1
(43) Pub. Date: Nov. 8, 2012

(54) TOUCH SENSOR WITH MODULAR COMPONENTS

(75) Inventors: Richard L. ST. PIERRE, North Andover, MA (US); Sundar Regmi, Woburn, MA (US); Kenneth J. Keefer, Westford, MA (US)

(73) Assignee: 3M Innovative Properties Company

(21) Appl. No.: 13/101,584

(22) Filed: May 5, 2011

(51) Int. Cl. G06F 3/043; H01L 41/22; H05K 3/30

(52) U.S. Cl. 345/177; 29/832; 29/25.35

(57) ABSTRACT

A bending wave-type touch sensitive device for resolving moving and stationary contacts made to a substrate, the touch sensitive device comprised of a plurality of transducer boards coupled to a substrate.

### BACKGROUND

A touch sensitive device offers a simple, intuitive interface to a computer or other data processing device. Rather than using a keyboard to type in data, a user can transfer information by touching an icon or by writing or drawing on a touch sensitive panel. Touch panels are used in a variety of information processing applications. Interactive visual displays often include some form of touch sensitive panel. Integrating touch sensitive panels with visual displays is becoming more common with the emergence of next generation portable multimedia devices such as cell phones, personal data assistants (PDAs), and handheld or laptop computers. It is now common to see electronic displays in a wide variety of applications, such as teller machines, gaming machines, automotive navigation systems, restaurant management systems, grocery store checkout lines, gas pumps, information kiosks, and hand-held data organizers, to name a few.

Various methods have been used to determine the location of a touch on a touch sensitive panel. Touch location may be determined, for example, using a number of force sensors coupled to the touch panel. The force sensors generate an electrical signal that changes in response to a touch. The relative magnitudes of the signals generated by the force sensors may be used to determine the touch location.

Capacitive touch location techniques involve sensing a current change due to capacitive coupling created by a touch on the touch panel. A small amount of voltage is applied to a touch panel at several locations, for example, at each of the touch screen corners. A touch on the touch screen couples in a capacitance that alters the current that flows from each corner. The capacitive touch system measures the currents and determines the touch location based on the relative magnitudes of the currents.

Resistive touch panels are typically multilayer devices having a flexible top layer and a rigid bottom layer separated by spacers. A conductive material or conductive array is disposed on the opposing surfaces of the top and bottom layers. A touch flexes the top layer causes contact between the opposing conductive surfaces. The system determines the touch location based on the change in the touch panel resistance caused by the contact.

Touch location determination may rely on optical or acoustic signals. Infrared techniques used in touch panels typically utilize a specialized bezel that emits beams of infrared light along the horizontal and vertical axes. Sensors detect a touch that breaks the infrared beams.

Surface Acoustic Wave (SAW) touch location processes uses high frequency waves propagating on the surface of a glass screen. Attenuation of the waves resulting from contact of a finger with the glass screen surface is used to detect touch location. SAW typically employs a “time-of-flight” technique, where the time for the disturbance to reach the pickup sensors is used to detect the touch location. Such an approach is possible when the medium behaves in a non-dispersive manner, such that the velocity of the waves does not vary significantly over the frequency range of interest.

Bending wave touch technology senses vibrations created by a touch in the bulk material of the touch sensitive substrate. These vibrations are denoted bending waves and may be detected using sensors typically placed on the edges of the substrate. Signals generated by the sensors are analyzed to determine the touch location.

### SUMMARY

In one embodiment, a contact sensitive device is described, comprising a first substrate capable of propagating bending wave vibration and having a touch surface; at least one transducer board coupled to the substrate, the transducer board including a second substrate onto which is mounted a sensor for measuring bending wave vibration of the first substrate and an emitter for generating bending wave vibration of the first substrate; and a processor communicatively coupled to the at least one transducer board for processing information from the sensor and emitter related to a contact made on the touch surface.

In another embodiment, a contact sensitive device is described, the contract sensitive device comprising a first substrate capable of propagating bending wave vibration and having a touch surface; at least one transducer board coupled to the substrate, the transducer board including a second substrate onto which is mounted a sensing transducer for measuring bending wave vibration of the first substrate, and an emitting transducer for providing a bending wave vibration to the first substrate; and a processor communicatively coupled to the at least one transducer board for processing contact-related information from the sensing transducer related to a contact made on the touch surface.

In another embodiment, a circuit board is described, the circuit board having at least four conductive pads on a first circuit board surface, the two conductive pads each having a surface area; a sensing transducer capable of sensing bending waves, the sensing transducer having at least two sensing transducer conductive connection points on a first sensing transducer surface, the first sensing transducer surface having a sensing transducer surface area; an emitting transducer capable of providing bending waves, the emitting transducer having at least two emitting transducer conductive connection points on a first emitting transducer surface, the first emitting transducer surface having an emitting transducer surface area; wherein at least a portion of each of two of the conductive pads are mechanically and electrically coupled to at least two areas of the first sensing transducer surface that include the two sensing transducer conductive connection points; and wherein at least a portion of each of the remaining two conductive pads are mechanically and electrically coupled to at least two areas of the first emitting transducer surface that includes the two emitting transducer conductive connection points.

In another embodiment, a method of making a touch sensitive device is described, the method comprising mechanically coupling at least three transducer boards to a substrate, the transducer boards each including at least a piezoelectric sensor capable of sensing bending waves and providing electrical signals indicative of sensed bending waves, wherein and at least one of the transducer boards additionally includes a piezoelectric emitter for providing bending waves to the substrate; and communicatively coupling the at least three transducer boards to electronics, the electronics configured to receive and transmit signals from the piezoelectric sensor and emitter and based on these signals provide signals indicative of the coordinates of a contact made to the substrate.

These and other embodiments are more fully described herein and with reference to the figures.

### BRIEF DESCRIPTION OF DRAWINGS

FIG. 1 is a drawing of the corner of touch sensor.

FIG. 2 is a drawing of a transducer board.

FIG. 3 is a drawing of a touch sensor and controller.

FIG. 4 is a drawing of a circuit board substrate of a transducer board.

FIG. 5 is a graph illustrating the Welch Power Spectral Density Estimate of transducer board configurations.

### DETAILED DESCRIPTION

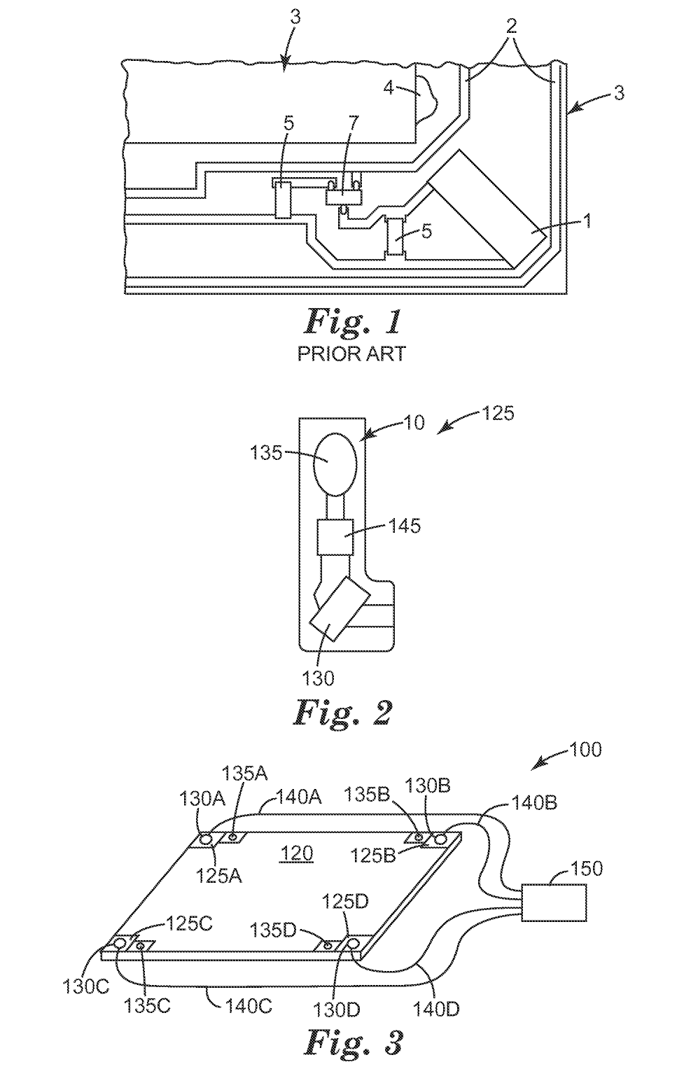

FIG. 1 is a drawing of the corner of a bending wave-type touch screen, such as that sold under the trade name MicroTouch DST by 3M Touch Systems, Methuen, Mass. Glass 3 has upon it conductive traces 2, which are electrically coupled to electrical components (two resistors 5 and a field effect transistor 7), which are in turn coupled via the conductive traces to piezoelectric sensor 1. These conductive traces and electrical components embody a voltage buffer circuit that connects high impedance input from the piezoelectric sensor into a low impedance output that goes to the controller (thus reducing noise interference and signal loss). This design has certain limitations. For example, it is necessary to print conductive traces onto the glass, which necessitates printing and baking equipment tailored to the glass sizes, which in turn makes scaling to new sizes difficult. Further, effectively securing the piezoelectric sensor directly on the glass requires a special process, as does placing the electrical components. Also, the conductive traces 2 may “bleed” in certain environmental conditions, potentially compromising the circuits formed by the conductive traces. Also, the conductive traces are susceptible to electrical noise from other components from, for example, a display device that would likely be in proximity to the touch screen. The noise issue is dealt with in the touch sensor shown in FIG. 1 using shielding tape 4, which is applied on the glass side opposite the conductive traces, but the application of the tape is yet another process step and material cost. Combined, these aspects of the design shown in FIG. 1 lend themselves to a number of process steps that involve the handling and manipulation of large sheets of glass.

The present invention relates to an apparatus that may, in some embodiments, address certain of these limitations, or provide new benefits not relating to these limitations. Further, this invention relates to an apparatus that may enable new devices or applications that are not tied to any of the aforementioned limitations. Further, this invention relates to new methods of making a touch sensitive device.

In the following description of the illustrated embodiments, reference is made to the accompanying drawings that form a part hereof, and in which is shown by way of illustration, various embodiments in which the invention may be practiced. It is to be understood that the embodiments may be utilized and structural changes may be made without departing from the scope of the present invention.

A touch sensing apparatus implemented in accordance with the present invention may incorporate one or more of the features, structures, methods, or combinations thereof described herein. It is intended that such a device, or method as the case may be, need not include all of the features and functions described herein, but may be implemented to include selected features and functions that, in combination, provide for useful structures and/or functionality.

The present invention relates to touch activated, user interactive devices and methods that provide for both sensing vibrations that propagate through a substrate, and also the emitting of vibrations to propagate through the substrate. More particularly, the present invention relates to touch sensing devices and methods that employ emitting and sensing transducers, the emitting transducers configured to generate bending wave vibrations in a substrate, and the sensing transducers configured to sense bending wave vibrations that propagate through a substrate, and to determine therefrom contact and movement location information using disparate touch location detection techniques. Contact sensing devices, associated algorithms, and techniques used to resolve data from sensing transducers into a touch location on the substrate are described in U.S. Pat. No. 7,157,649 “Contact Sensitive Device” (Hill); U.S. Pat. No. 6,871,149 “Contact Sensitive Device” (Sullivan et. al.); U.S. Pat. No. 6,922,642 “Contact Sensitive Device” (Sullivan); U.S. Pat. No. 7,184,898 “Contact Sensitive Device” (Sullivan et. al.); “Touch Sensitive Device Employing Bending Wave Vibration Sensing and Excitation Transducers” U.S. Pat. No. 7,411,584 (Hill); “Touch Sensing with Touch Down and Lift Off Sensitivity” U.S. Pat. No. 7,277,087 (Hill et. al); US Pat. application publication no. 2006/0244732, “Touch Location Determination using Bending Mode Sensors and Multiple Detection Techniques” (Geaghan); and in US Pat. application publication no. 2010/0253648, “Touch Sensor with Modular Sensing Components” (St. Pierre), the contents of each of which is hereby incorporated by reference in its entirety.

The term bending wave vibration refers to an excitation, for example by a physical contact or by an emitting transducer, which imparts some out of plane displacement to a member capable to supporting bending wave vibrations. Many materials bend, some with pure bending with a perfect square root dispersion relation and some with a mixture of pure and shear bending. The dispersion relation describes the dependence of the in-plane velocity of the waves on the frequency of the waves. The term bending may also apply to out of plane displacement or deflection of a member when subject to loading, such as when a touch panel deflects (for example, is subject to bowing) in response to a touch applied to the surface of the touch panel. In this regard, one surface of the touch panel is placed in compression, while the opposing surface is placed in tension, which results in bowing of the touch panel. Such bowing of the touch panel may be detected using bending mode sensors of a type described herein and in a manner discussed below.

In vibration sensing touch input devices that include piezoelectric sensors, for example, vibrations propagating in the plane of the touch panel plate stress the piezoelectric sensors, causing a detectable voltage across the sensor. The signal received can be caused by a vibration resulting directly from the impact of a direct touch input or the input of energy due to a trace (friction), or by a touch input influencing an existing vibration, for example by attenuation of the vibration, or by the vibration of the emitting piezoelement. The signal received can also be caused by an unintended input, such as an input resulting from user handling or mishandling of the touch input device, or from environmental sources external to, but sensed by, the touch input device.

Turning to FIG. 2, a drawing of a transducer board 125 is shown. The term “transducer board” refers to a component including a substrate suitable for mounting electronics (for example, a circuit board), a sensor capable of detecting bending waves, an emitter capable of generating bending waves and associated electronics as needed to provide electronic signals indicative of the bending waves. For example, in one embodiment as provided in FIG. 2, the transducer board includes circuit board 10 onto which is mounted sensor 130 (in this case a piezoelectric sensor that produces a voltage when deformed, for example, by bending waves propagating through the substrate due to a contact event) and emitter 135. The sensor board illustrated in FIG. 2 also includes a signal conditioning circuit, and connection points for wires leading to electronics (not shown in FIG. 2) that receive signals from the transducer board and process those signals into, in some embodiments, the two dimensional coordinates of a touch event on the substrate. Such electronics also may provide signals via the wires that cause emitter 135 to vibrate, thereby generating bending wave vibrations in substrate 10.

Signal conditioning circuit 145 includes analog circuitry to condition signals coming from sensor, or going to emitter, from, for example, controlling electronics. For example, in one embodiment, signal conditioning circuit may include an amplifier or a buffer to convert the high impedance of a piezoelectric sensor to a signal more compatible with the data processor, in order to minimize electrical noise.

Sensors 130 and emitters 135 are preferably piezoelectric transducers that can sense vibrations indicative of a contact input to substrate, as will be more fully described below. Useful piezoelectric transducer constructions include unimorph or bimorph in rectangular, circular, semi-circular, or annular shape. Piezoelectric transducers offer a number of advantageous features, including, for example, good sensitivity, relative low cost, adequate robustness, potentially small form factor, adequate stability, and linearity of response. Other transducers that can be used in vibration sensing touch sensitive devices include electrostrictive, magnetostrictive, piezoresistive, acoustic/ultrasonic, capacitive, and moving coil transducers/devices, among others.

The emitting transducer generates bending waves on the touch surface based on the excitation frequency of operation. The emitting transducer in one embodiment is always on, and in another embodiment is selectively turned on or off depending on whether software and associated electronics determine the existence of an operating environment that would benefit from enhanced detection of some types of contacts, as may be provided by having the emitting transducers “on.” In one embodiment, the emitting transducer is disk-shaped and planar (radial in all directions) relative to the plane of touch surface. The emitting transducer provides bending waves which are sensed by the sensing transducer. If the emitting transducer is on (i.e., emitting vibrations), then a contact made to a touch surface would generate its own bending waves at the point of contact, and also would change the manner in which bending waves emitted from the emitting transducer propagate through the substrate. In some operational environments, sensed bending waves associated with both the contact and the disruption of emitted vibrations provides more sensitive and accurate determination of touch positions than either alone. Particularly, in some embodiments, sensing disruptions in emitted vibrations provides for better determination of a drag-type contact, where for example a finger is lightly pulled across a contact surface, or the removal of a contact from the contact surface (a so-called lift-off event). Both the drag-type contact and the lift-off event both may involve minimal creation of bending waves by themselves, but both may be more readily sensed by how they modify emitted waves from emitter 135.

In one embodiment, the frequency of operation of emitting transducer is lower than the resonant frequency of the emitting transducer and below the higher cutoff frequency of sensing transducer. The sensing transducer senses bending waves generated by both a touch as well as the emitting transducer. The sensitivity of the sensing transducer at two frequency ranges depends on the frequency response of the sensing transducer which may not be constant across the entire frequency of operation. The bending wave vibration generated by the emitting transducer is used to determine, for example, a lift-off event. The emitting transducer operates on the frequency band different from that of rest of the touch detection system and it doesn't unacceptably interfere with vibrations generated by tap, and drag-type contacts. Thus, it is possible to have an emitter and a sensor on the same transducer board.

Turning now to FIG. 3, there is illustrated one configuration of a touch sensitive device 100 that incorporates features and functionality for detecting bending wave vibrations and determining touch location using a multiplicity of disparate touch location detection techniques. According to this embodiment, the touch sensitive device 100 includes a substrate 120 and transducer boards 125 (which include vibration sensors 130A-D and emitters 135A-D) which are in turn coupled to an upper surface of the substrate 120. In this illustrative example, the upper surface of the substrate 120 defines a touch sensitive surface. Although sensors 130 and emitters 135 are shown coupled to the upper surface of the substrate 120, the transducer boards 125 can alternatively be coupled to the lower surface of the substrate 120. In another embodiment, one or more transducer boards 125 may be coupled to the upper surface while one or more other transducer boards 125 may be coupled to the lower surface of the touch substrate 120. The transducer boards 125A-125D can be coupled to touch plate 120 by any suitable means, for example using an adhesive or other suitable material, so long as the mechanical coupling achieved is sufficient for vibrations propagating in the touch plate to be detected by the vibration sensors. Further discussion on mounting transducer boards to the substrate is provided below. Exemplary vibration sensors 130 and vibration sensor arrangements are disclosed in co-assigned U.S. Pat. Applications U.S. Ser. No. 10/440,650 (Robrecht) and U.S. Ser. No. 10/739,471 (Hill), which are fully incorporated herein by reference into this document.

Substrate 120 may be any substrate that supports vibrations of interest, such as bending wave vibrations. Exemplary substrates 120 include plastics such as acrylics or polycarbonates, glass, steel, aluminum, or other suitable materials. In general, any material whose dispersion relation is known could be used. Touch substrate 120 can be transparent or opaque, and can optionally include or incorporate other layers or support additional functionalities. For example, substrate 120 can provide scratch resistance, smudge resistance, glare reduction, anti-reflection properties, light control for directionality or privacy, filtering, polarization, optical compensation, frictional texturing, coloration, graphical images, and the like. In one embodiment, substrate 120 is a rectangular piece of glass. In another embodiment, substrate 120 is a sheet-type substrate in that it is thin relative to its length and width. In some embodiments, substrate 120 is of relatively uniform thickness. Pat. App. No. 61/080,966 “Systems and Methods for Correction of Variations in Speed of Signal Propagation Through a Touch Contact Surface” describes methods and algorithms for compensating for variances in the uniformity of the substrate, and is fully incorporated herein by reference into this document. Substrate 120 may be very large, in sizes well exceeding 55″ in the diagonal. For example, substrate 120 may be 60″, 70″, 80″, 90″ or even 100″ in the diagonal. Even larger sizes are conceivable, limited only by the size where vibrations become too small to be detected by the sensors.

Substrate 120 may be already incorporated into some other application not necessarily intended for use as a touch-sensitive device. For example, the transducer boards could be affixed to the glass on a window.

In some embodiments, substrate 120 includes conductive traces running near its edges to reduce the profile of electrical connectors 140. In general, the touch sensitive device 100 includes at least three transducer boards 125 wherein at least two transducer boards include both sensor and emitter to determine the position of a touch input in two dimensions. In one preferred embodiment, touch sensitive device includes four transducer boards 125 (shown as transducer boards 125A, 125B, 125C, and 125D in FIG. 3), with each including both a sensor and an emitter. Another preferred embodiment includes four transducer boards, two of which include sensors and emitters, and two including sensors only. Various configurations and arrangements of sensors may be desirable in some embodiments, as discussed in U.S. Pat. No. 6,922,642 (Sullivan), U.S. Pat. No. 7,157,649 (Hill), U.S. Pat. No. 7,277,087 (Hill), and in co-assigned U.S. patent application Ser. No. 09/746,405, each of which are fully incorporated herein by reference into this document. In some embodiments where precise coordinates of a touch event are not needed, less transducer boards 125 may be used. For example, one transducer board 125 may be used in applications where two dimensional resolution requirements are less restrictive. For example, in a display device for example in advertising, a touch sensitive device 100 may be used in conjunction with a display (such as an LCD display) which displays instructions to would-be users advising them to “Touch Screen to Begin.” In such an embodiment, the two dimensional coordinates of the touch location would not be necessary. Also, embodiments deploying only two transducer boards 125 may provide somewhat more resolution in determining whether particular areas of the screen have been touched. For example, in the above advertising example, the touch sensitive device coupled with a display may instead solicit input from would-be users with a message in two discreet areas of the screen: “Touch Here to Begin in English” and “Touch Here to Begin in Spanish.” In such case, depending on the placement of the discreet areas on the screen, it may not be necessary to include four transducer boards to meet the touch resolution requirements. In this particular example, two transducer boards could likely provide adequate resolution.

In one embodiment, all of the sensors 130 are configured to sense vibrations in the touch substrate 120. The sensors 130 may be substantially the same in terms of technology and functionality. For example, all of the sensors 130 may be bending mode sensors produced by a particular manufacturer under the same part number or identification. In other embodiments, the sensors 130 may be substantially the same in terms of technology, but differ in terms of functionality. For example, all of the sensors 130 may be bending mode sensors produced by a particular manufacturer, with some of these sensors implemented to detect bending waves and other sensors implemented to detect plate deflection. In some embodiments, one or more of the sensors 130 may be a sensor other than a bending mode sensor.

Many applications that employ touch sensitive devices 100 also use electronic displays to display information through the touch sensitive devices 100. Such displays include, for example, liquid crystal displays, plasma displays, and organic light emitting diode displays. Since displays are typically rectangular, it is typical and convenient to use rectangular touch sensitive devices 100. As such, the touch substrate 120 to which the sensors 130 are affixed is typically rectangular in shape, it being understood that other geometries may be desirable.

Using a piezoelectric transducer to provide bending waves, which are then sensed by other transducers, is more fully described in the following references, each of which has been earlier incorporated by reference: U.S. Pat. Nos. 6,922,642; 7,157,649, and 7,411,584.

According to one configuration, the transducer boards 125A, 125B, 125C, 125D are preferably placed near the corners of the substrate 120. Because many applications call for a display to be viewed through the touch sensitive devices 100, it is desirable to place the transducer boards 125A-D near the edges of the touch substrate 120 so that they do not undesirably encroach on the viewable display area. Placement of the transducer boards 125A-D at the corners of a touch substrate 120 can also reduce the influence of acoustic reflections from the substrate edges.

The contact sensed by the touch sensitive device 100 may be in the form of a touch from a stylus, which may be in the form of a hand-held pen. The movement of a stylus on the touch substrate 120 may generate a continuous signal, which is affected by the location, pressure and speed of the stylus on the touch substrate 120. The stylus may have a flexible tip, for example of rubber, which generates bending waves in substrate 120 by applying a variable force thereto. The variable force may be provided by the tip, which alternatively adheres to or slips across a surface of the substrate 120. Alternatively, the contact may be in the form of a touch from a finger that may generate bending waves in the touch substrate 120, which may be detected by passive and/or active sensing. The bending waves may have frequency components in the ultrasonic region (>20 kHz).

The touch sensitive device 100 shown in FIG. 3 is communicatively coupled to a controller 150. The transducer boards 125A-D are communicatively coupled to the controller 150 via conductors (for example, wires) or a printed electrode pattern developed on the touch substrate 120. The controller 150 typically includes front end electronics that measure signals or signal changes from the sensors on the transducer boards 125A-D. Additionally, controller 150 may include electronics that activate the emitting transducers included on transducer boards 125A-D. In other configurations, the controller 150 may further include a microprocessor in addition to front end electronics. The controller 150, as is described in detail below, is capable of implementing one or more touch location detection techniques selected from a library of disparate touch location detection techniques, as is described, for example, in patent application publication no. 2006/0244732, “Touch Location Determination using Bending Mode Sensors and Multiple Detection Techniques” (Geaghan), which was earlier incorporated by reference into this document.

In a typical configuration, the touch sensitive device 100 is used in combination with a display of a host computing system (not shown) to provide for visual and tactile interaction between a user and the host computing system. The host computing system may include a communications interface, such as a network interface, to facilitate communications between a touch panel system that incorporates touch sensitive device 100 and a remote system. Various touch panel system diagnostics, calibration, and maintenance routines, for example, may be implemented by cooperative communication between the touch panel system and the remote system.

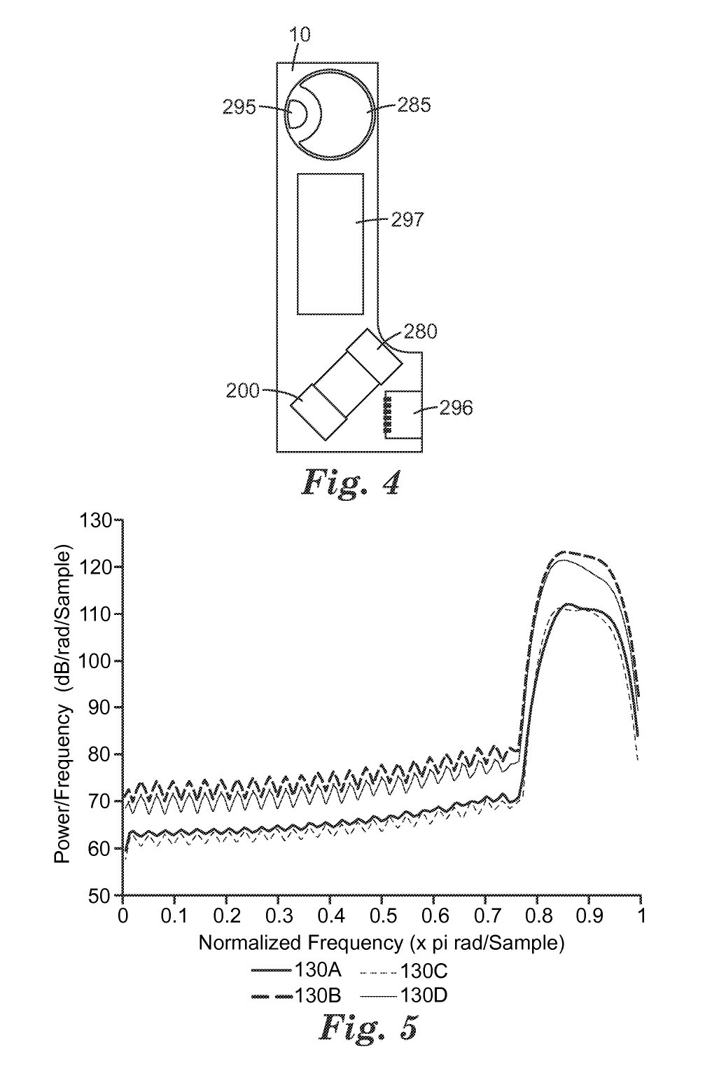

Turning to FIG. 4, a drawing of a transducer board is shown. It is similar to that shown with respect to FIG. 2, except it provides somewhat more detail. The transducer board includes circuit board 10 onto which is mounted a sensor having connection ends 200 and 280 (in this case a piezoelectric sensor that produces a voltage when deformed, for example, by bending waves propagating through the substrate due to a contact event) and a disc-shaped emitter having connection points 295 and 285. The sensor board illustrated in FIG. 4 also includes a signal conditioning circuit 297, and connection points for wires leading to electronics (not shown in FIG. 2) that receive signals from the transducer board and process those signals into, in some embodiments, the two dimensional coordinates of a touch event on the substrate. Connection jumper 296 provides a convenient way to couple communication wires to the transducer board.

Using transducer boards in configurations described herein may provide certain benefits. For example, a display manufacturer interested in producing touch-sensitive displays could purchase a kit containing transducer boards 125 and associated electronics, or just the transducer boards 125 if the electronics are already incorporated into the electronics for the touch-sensitive display. The display manufacturer is then afforded a great deal of flexibility in determining the particulars of how the assembly process could be most efficiently adapted to accommodate the step of affixing the transducer boards.

### Calibration

Given the distance from a tap point to each of the transducer boards, as well as the thickness, density, and Young's modulus of the substrate, a relatively straightforward calibration process may be used to fine-tune resolution of touch points. For example, the substrate may be tapped at a known location, then the signals measured by the sensor transducer on the transducer boards, yielding data. Using this data, along with the locations of the transducer boards and the physical properties of the substrate, an accurate model of the substrate can be determined and used to calculate touches in unknown locations. Additional points may be tapped to further refine calibration.

### Transduction Considerations

The piezoelectric sensor (sensor 130 in FIG. 2 and FIG. 3) is designed to measure bending waves in substrate 120. These bending waves are generally high frequency (5-20 kHz). Likewise, the emitter (emitter 135 in FIGS. 2 and 3) is designed to generate bending waves in substrate 120. The interfaces and layers between sensor 130 and substrate 120 must not unacceptably attenuate these vibrations.

### Transducers to Circuit Board Interface

The mounting of the piezoelectric transducers (both the sensor and the emitter) to the circuit board is an important factor in achieving good transduction of bending waves in the substrate. The mechanical bond between the circuit board and piezoelectric transducer must be strong enough and preferably of uniform thickness, in order to fully couple the substrate 120 vibrations to the sensor 130 and to fully transmit emitter 135 vibrations to the substrate 120. Adequate test results were achieved when about 50% of total surface area of the side of the piezoelectric transducer electrodes were mechanically coupled (via solder or conductive epoxy) to the pads 200. It is expected that adequate results could be similarly achieved with as low as about 20% of the total surface area of the side of the sensor having electrodes being mechanically coupled to the sensor pads.

### Circuit Board

The circuit board itself is an interface between the piezoelectric transducers (130 and 135) and substrate 120. Typical FR-4 (a type of flame retardant material commonly used for circuit boards) circuit board material did not have a substantial adverse effect on the transmitted vibrations.

### Circuit Board to Substrate Interface

Initial testing of transducer boards for this interface used an adhesive sold under the trade name of “Instant ‘Krazy’ Glue”, a cyanoacrylate adhesive. Performance was adequate. In practice any adhesive which can withstand the normal temperature of operation, for example, 40 to 50 degrees C. and still maintain the rigid and thin bond line could be used.

In one embodiment, the transducer board is designed so sensor 130 is properly aligned on the substrate if the transducer board is bonded using the glass edges as a guide. In this way, the proper positioning of the sensor can be controlled.

### Wiring Considerations

Transducer boards need to be communicatively coupled to the controller 150. In one embodiment, this is accomplished by means of a thin wiring harness composed of conductors or a flex circuit that is adhered to the substrate.

In some embodiments, a potential advantage of using a wiring harness, as opposed to conductive traces described with respect to FIG. 1, is the ability to minimize noise contamination from a nearby display, other electronics, or external sources. For example, both LCD and plasma displays generate a significant amount of high frequency noise that may be picked up by the silver traces on the touch panel. To deal with this issue, current bending wave sensitive touch panels may have copper tape applied to the outside border to help shield the traces from external noise sources.

By using the transducer board design concepts discussed herein, a wiring harness could include a shielded wire or a shielded (multi-layer) flex circuit. An alternative method would be to use twisted pair wiring instead of shielding. This would minimize interference from both internal and external noise sources. The circuit board could also have a ground plane as a second layer to minimize interference on the circuit (or alternatively, use a conductive epoxy that is connected to ground). With these shielding improvements, it is likely that the signal-to-noise ratio seen by the controller will be increased, resulting in better performance and easier adaptation to larger size panels.

Another advantage of the shielding, in certain embodiments, is enhanced electrostatic discharge (ESD) protection. It is expected that a design incorporating several of the shielding techniques discussed above would be able to meet ESD requirements exceeding 27 kV.

Frequency Response using Circuit Boards

To test the response of transducer boards as thusly described, four respective pairs of a sensor transducer and an emitter transducer were mounted upon four 30 mil thick FR-4 substrates. The four resulting transducer boards were then adhered to corners of a 46″ (diagonal) rectangular glass substrate using the cyanoacrylate adhesive mentioned above, resulting in a configuration similar to that showed with respect to transducer boards 125 in FIG. 3. The sensor and the emitter were then coupled to a controller using flat flexible cable that was connected to the transducer board using zero insertion force (ZIF) connectors. The cables, each comprised of a plurality of discreet conductors, were not shielded from external noise sources, though such shielding may in some embodiments be desirable. A multi-sine wave was used to drive emitters associated with two of the four transducer boards and the response at each of the four sensors was measured. The two emitters that were driven were on top left and top right. In some preferred embodiments, it is desirable to have symmetry between the left and right portions of the substrate, with respect to emitter placement, if possible. For these tests, the glass substrate was mounted on a display of similar size.

FIG. 5 shows the spectral density estimate (Welch's method) responses for each sensors 130A, 130B, 130C, and 130D when emitters 135B and 135D were excited. The results show that none of the corner responses were bleeding to the moving touch detection and localization frequency range of operation (below 0.75 normalized frequency) and measured responses were strictly within the frequency range of driving signal. The signal to noise ratio for each corner is good given the size of the touch sensitive device. FIG. 5 also shows that the emitting transducer does not generate bending wave vibrations of lower frequency (as could possibly interfere with vibrations emanating from contact type and drag type events) and hence there is essentially no interference to vibrations generated below 0.75 normalized frequency.

### DETAILED EXAMPLE

A bending wave touch sensitive device using transducer boards was constructed and tested as described below.
1) The substrate consisted of a rectangular plate of soda-lime float glass measuring 752 mm×433 mm (27.63″×17.07″) and 2.2±0.1 mm (0.087″±0.004″) thick, obtained from Europtec Gmbh of Goslar, Germany. The glass had an anti-glare acid etch applied to the front surface. The glass had been chemically strengthened to a tensile strength≧180 N/mm2. The optical transmittance was >91%. The edges of the glass had been ground and rounded to have a radius≧half of the glass thickness.
2) Transducer boards were constructed and attached to each of the four corners of the non-etched surface (opposite the touch surface) of the glass plate. The transducer board substrates were L-shaped pieces of typical commercial FR-4 circuit board material measuring approximately 10-10.2 mm×14.4 mm×31.4-39.0 mm (0.394-0.403″×0.565″×1.235-1.535″) and 0.76 mm (0.030″) thick. The circuit boards were then patterned with appropriate metallic circuit traces and solder pads, as will be described below.
3) The sensor for measuring bending wave vibrations on each transducer board was a piezoelectric sensor having a resonant frequency of 570 kHz±20%. The sensors were 4.5±0.1 mm (0.177±0.004 inches) wide, 10.4±0.1 mm (0.409±0.004 inches) long and 1.1±0.1 mm (0.043±0.004 inches) thick. A mark on the top of the transducer indicated the positive poling direction.
4) Each sensor was provided with an amplifier circuit on its transducer board, to convert the high impedance of the piezo to a signal more compatible with the data processor, in order to minimize electrical noise.
5) The emitter for generating bending wave vibration on each transducer board was a piezoelectric transducer having dimensions of 7.4±0.1 mm (0.290±0.004 inches) diameter, and 0.38±0.1 mm (0.015±0.004 inches) thick. The material of piezoelectric element was chosen in order to have the capacitance suitable for an emitter.
6) The piezoelectric elements were attached to the transducer board using the conductive epoxy H2OE-PFC sold by Epoxy Technology, Inc. under the trade name of “EPO-TEK.” The conductive epoxy is a two component, semiconductor grade epoxy, designed for flip chip interconnects using a solder-free joining method. After the piezoelectric elements had been adhered in place, the amplifier circuit was also soldered in place on the circuit board. The resulting transducer board was schematically similar to that shown in FIG. 2.
7) The assembled transducer boards were next attached to the corners of the touch surface of the glass plate using the cyanoacrylate adhesive reference above.
8) Flat Flexible Cables (FFCs) were used to connect transducer boards to controller. FFCs were mated on both ends to ZIF connectors on each circuit board. FFCs were obtained from Printed Electronics Co. Inc and ZIF connectors were obtained from Molex Incorporated. These leads were then connected to a standard DST controller, of the type currently available from 3M Touch Systems, Inc., Methuen, Mass., USA.
9) The touch sensitive device then had mounting foams (3M™ VHB Acrylic Foam Tape 5925 and 3M™ VHB Acrylic Foam Tape 5962, available from 3M Company, St. Paul, Minn., USA) applied to the four edges of the touch sensor, as is standard for integrating a 3M™ DST bending wave touch sensor onto the front of a display device. The sensor was then mounted in a 46″ diagonal liquid crystal display for the remainder of the tests.
10) The touch sensitive device attached to the 46″ display was tested for taps. The performance was shown to be acceptable. The device was also tested for drag-type contact and lift-off events. In each test for lift-off event (an event well suited to test the emitter, sensor combination), the electronics successfully registered all of events.

Manufacturing touch sensitive bending-wave type panels using transducer boards as described herein could significantly reduce the cost of equipment needed to produce traditional bending wave-type touch sensors, which often require screen printers (for printing conductive traces) and ovens (for curing the conductive traces). Such printers and ovens may not be required given certain embodiments disclosed herein.

Further, in some embodiments, a kit containing transducer boards, wiring, and the controller board (or some combination of these things, or additional things such as adhesive for securing the transducer board to the substrate) could be purchased by a customer interested in manufacturing a touch sensitive substrate. For example, an LCD manufacturer could source its own glass substrate then assemble a touch sensitive panel using the above mentioned kit. This may afford the LCD manufacturer a great deal of manufacturing flexibility and cost savings.

A number of embodiments have been described above. The invention, however, may be embodied in many different forms and should not be construed as limited to the embodiments set forth herein; rather, these embodiments are provided so that this disclosure will be thorough and complete, and will fully convey the scope of the invention to those skilled in the art.

Many modifications and other embodiments of the invention will come to mind to one skilled in the art to which this invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims.

What we claim is:

1. A contact sensitive device comprising:
a first substrate capable of propagating bending wave vibration and having a touch surface;
at least one transducer board coupled to the substrate, the transducer board including a second substrate onto which is mounted a sensing transducer for measuring bending wave vibration of the first substrate, and an emitting transducer for providing a bending wave vibration to the first substrate; and
a processor communicatively coupled to the at least one transducer board for processing contact-related information from the sensing transducer related to a contact made on the touch surface.

2. The contact sensitive device of claim 1, wherein the processor additionally processes lift-off information from the sensing transducer related to a lift-off of the contact made on the touch surface.

3. The contact sensitive device of claim 2, wherein the processor is additionally communicatively coupled to the emitting transducer, and the processor provides signals to the emitting transducer that cause it to vibrate and thereby apply bending wave vibrations to the first substrate.

4. The contact sensitive device of claim 3, wherein the contact-related information is based on the bending wave vibrations applied to the substrate by the emitting transducer and received by the sensing transducer.

5. The contact sensitive device of claim 1, wherein processing contact-related information comprises resolving the X and Y coordinates of the contact made to the touch surface.

6. The contact sensitive device of claim 3, wherein processing the contact-related information comprises resolving the X and Y coordinates of the lift off of the contact made to the touch surface.

7. The contact sensitive device of claim 5, wherein the transducer board is coupled to the first substrate using an adhesive.

8. The contact sensitive device of claim 5, wherein the first substrate is a sheet of glass.

9. The contact sensitive device of claim 8, wherein the sheet of glass is of uniform thickness.

10. The contact sensitive device of claim 5, wherein the first substrate is transparent or semi-transparent and has four corners, and wherein the at least one transducer board comprises four transducer boards, which are coupled proximate the four corners of the substrate.

11. The contact sensitive device of claim 10, further comprising:
a display device positioned proximate the first substrate to provide visual stimuli through the first substrate.

12. The contact sensitive device of claim 11, further comprising:
a computer communicatively coupled to the display device to control visual stimuli on the display, and wherein the processor is further communicatively coupled to the computer and provides information indicative of coordinates of contacts made to the display device.

13. The contact sensitive device of claim 1, wherein the emitter is a disc-shaped piezoelectric transducer.

14. An apparatus comprising:
a circuit board having at least four conductive pads on a first circuit board surface, the two conductive pads each having a surface area;
a sensing transducer capable of sensing bending waves, the sensing transducer having at least two sensing transducer conductive connection points on a first sensing transducer surface, the first sensing transducer surface having a sensing transducer surface area;
an emitting transducer capable of providing bending waves, the emitting transducer having at least two emitting transducer conductive connection points on a first emitting transducer surface, the first emitting transducer surface having an emitting transducer surface area;
wherein at least a portion of each of two of the conductive pads are mechanically and electrically coupled to at least two areas of the first sensing transducer surface that include the two sensing transducer conductive connection points; and
wherein at least a portion of each of the remaining two conductive pads are mechanically and electrically coupled to at least two areas of the first emitting transducer surface that includes the two emitting transducer conductive connection points.

15. The apparatus of claim 14, wherein the surface area of the first sensing transducer surface that is mechanically coupled to two of the conductive pads is greater than 20% of the total first sensing transducer surface area.

16. The apparatus of claim 14, wherein both the sensing transducer and the emitting transducers are piezoelectric transducers.

17. The apparatus of claim 16 wherein the conductive pads are coupled to the first sensing transducer surface and the first emitting transducer surface using conductive epoxy.

18. A method of making a touch sensitive device comprising:
mechanically coupling at least three transducer boards to a substrate, the transducer boards each including at least a piezoelectric sensor capable of sensing bending waves and providing electrical signals indicative of sensed bending waves, wherein and at least one of the transducer boards additionally includes a piezoelectric emitter for providing bending waves to the substrate;
communicatively coupling the at least three transducer boards to electronics, the electronics configured to receive and transmit signals from the piezoelectric sensor and emitter and based on these signals provide signals indicative of the coordinates of a contact made to the substrate.

19. The method of claim 18, wherein the contact comprises a drag-type event or a lift-off event.

20. The method of claim 18, wherein at least two of the transducer boards additionally includes a piezoelectric emitter for providing bending waves to the substrate;

21. The method of claim 18, wherein mechanical coupling comprises using adhesive.

22. The method of claim 21, wherein communicatively coupling comprises electrically coupling using conductors.

23. The method of claim 22, wherein the substrate is glass.

24. The method of claim 23, further comprising:
mechanically coupling the substrate to a display device such that the display may be viewed through the substrate.
